(19) United States
(12) Patent Application Publication
(10) Pub. No.: US 2009/0267629 A1
(43) Pub. Date: Oct. 29, 2009

(54) Contact for interconnect system in a test socket

(75) Inventor: Wei Kuong Foong, Petaling Jaya (MY)

Correspondence Address: ABELMAN, FRAYNE & SCHWAB, 666 THIRD AVENUE, 10TH FLOOR, NEW YORK, NY, 10017, US

(73) Assignee: J. Foong Technologies Sdn. Bhd.

(21) Appl. No.: 12/386,778

(22) Filed: Apr. 22, 2009

(30) Foreign Application Priority Data
Apr. 23, 2008 (MY) PI20081225

(51) Int. Cl. G01R 31/02; G01R 1/067

(52) U.S. Cl. 324/755

(57) ABSTRACT

The present invention generally relates to testing of IC devices, and more specifically to a contact (11) for a test socket (1) for interfacing pads/leads (21) of the IC devices (2) with a printed circuit board (3) of a test handler. The contact (11) comprises a contact body (12), a first arm (13) adapted for electronically engaging the pads/leads (21) and a second arm (14) adapted for electronically engaging the corresponding terminals (31) on the printed circuit board (3). The first engaging means (15) is provided with a sliding means for improved sliding action between the contact (11) and the pads/leads (21). The sliding means enable a single contact to be used for various IC devices and also protects the pads/leads (21) and contacts (11) of the test socket (1) from damage and extensive wear.

### TECHNICAL FIELD OF THE INVENTION

The present invention generally relates to the field of integrated circuit devices (IC) testing. More particularly, the present invention relates to a contact in a test socket which interfaces with pads/leads of the IC devices with a printed circuit board of a test handler that protects both the IC pads/leads and contacts of the test socket from damage and extensive wear as well as allows good contact for the test to take place.

### BACKGROUND OF THE INVENTION

IC devices have many applications in today's industry. In order to provide for efficient, reliable and uninterrupted operation, such devices must be tested to ensure the device meets the high quality required of the electronics industry. Testing and burn-in of the IC device typically requires the devices to be actuated by engagement of their pads/leads, with corresponding contacts of a test socket. The contacts of the test socket, in turn, electronically communicate with terminals of a printed circuit board of a test socket of a test handler which is adapted to test the IC device in question. It is desirable that such IC devices could be tested either in manual mode or automatic mode of testing. In methods known in the art, “pick and place”, “turret” or “gravity feed” handling mechanism employs the modification of existing manual test sockets, in order to provide dedicated test sockets that are specifically adapted to interface with the test handler.

This type of test socket typically comprises of socket housing and an optional cover assembly for the manual mode testing. The socket housing is provided with an array of compliant contacts for electronically engaging the IC while the cover assembly is hinged at the socket housing. When a device is positioned in the test socket, the cover assembly is latched at the socket housing. The IC devices are aligned within the socket housing by various means to guide the pads/leads into engagement with the corresponding contacts within the test socket cavity.

In practice, contacts in test sockets are generally formed having W-shaped arms. The extremities of the upper and lower arms of the W-shaped body act as contacts that interconnect the pads/leads of the IC with the printed circuit board of the test handler. It is within the socket housing that the tips of the contacts are held. The contact is profiled appropriately for interfacing with the device by engagement of the contact tip and the pads/leads to provide the desired sliding action.

New IC devices such as the QFN/MLP have pads/leads where in the molding process of the same often has excessive molding flash or a solder mask that may impede good electrical contact required in the testing process. This often interferes with the contact probe thereby causing a test failure. A narrower solder mask in certain IC package designs also provides impediments to good contact and increases test failures due to the narrower test pads/leads. As such, the test yield is lost and re-test is needed, with the W-shaped preferably designed with narrower contact tip to enable to penetrate the narrower/recess or flat devices pads/leads for a good test. Therefore, there arises an un-met need for a new contact which can serve a plurality of IC devices having various pads/leads profiles and configurations.

The present invention discloses an improved test contact which functions to electronically interface the pads/leads of an IC device to be tested, with corresponding terminals of a printed circuit board. The device according to the present invention enables testing of similar pad configurations without the need to change the whole socket.

### SUMMARY OF THE INVENTION

Accordingly, it is the primary object of the present invention to provide a contact for electronically interfacing pads/leads of an integrated circuit device with corresponding terminals of a printed circuit board for testing of the same.

It is another object of the present invention to provide a contact that is mechanically and thermally stable for providing acceptably high accuracy testing and yet suitable for various pads/leads configurations.

It is yet another object if the present invention to provide a contact having a sliding action with the pads/leads for substantially improved penetration for better contact and also resistance against wear and tear.

These and other objects of the present invention are accomplished by,

In a test socket (1) for testing integrated circuit devices (2) of the like, a contact (11) is provided for electronically interfacing pads/leads (21) of said integrated circuit devices (2) to be tested with corresponding terminals (31) on a printed circuit board (3), said contact (11) comprises of:
a contact body (12), said contact body having a first arm (13) adapted for electronically engaging said pads/leads (21), said first arm (13) being provided with a first engaging means (15), and a second arm (14) adapted for electronically engaging said corresponding terminals (31) on said printed circuit board (3), said second arm (14) being provided with a second engaging means (16);
said first arm (13) and said second arm (14) being located at opposing extremities of said contact body (12); and
said first engaging means (15) is provided with a sliding means for improved sliding action with said pads/leads (21);
characterized in that:—
   said sliding means includes an engaging tip (25) integrally formed on said first engaging means (16), said engaging tip (25) having narrower cross-section at its top portion relative to said contact body (12).

The contact (11) is retained in the test socket for interfacing the pads/leads of the IC devices with a printed circuit board (3) of the test socket during testing. The contact has features that look substantially similar with the letter of W. The first arm (13) of the contact is adapted for electronically engaging pads/leads (21) of the IC devices to be tested. For improved engagement, the first arm (13) is provided with a first engaging means (15) having a sliding means in the form of tip projecting from top most of the first arm (13) as seen in FIG. 2a.

The second arm (14) is provided with the second engaging means (16) for electronically engaging the contact (11) to the corresponding terminals (31) of the printed circuit board (3) of the test socket (1). The first engaging means (15) provides improved sliding action with the IC pads/leads (21), and in the especially preferred mode of the invention, has a thickness less than that of the body of the contact (11) thereby providing means to avoid electrical contact impediments that present or formed on, or in-between the pads/leads. The curved exterior surfaces of contact (11) that formed along the first engaging means (15) and both arms of the body also help protect the pads/leads (21) and contacts (31) of the test socket from damage and extensive wear. A planar contact section (19) positioned to operatively engage with the pads/leads (21) provides additional good contact to the test socket. Further, the thickness of the first engaging means (15), at least at the contact section (19), is best if it is thinner than the thickness of the first arm (13). This feature is best shown in FIG. 2b. In the preferred embodiment, the preferred ratios of the thickness of the engaging tip (25) or at least the contact section (19) is from 20-40% of the thickness of the first arm (13) of the contact (11) thereby allowing the contact (11) to adapt to pads/leads (21) of varying width without having to change the contact (11).

### BRIEF DESCRIPTION OF THE DRAWINGS

Other aspects of the present invention and their advantages could be readily discerned after studying the Details Description in conjunction with the accompanying drawings in which:

FIG. 1 shows general view of a contact as installed in a test socket configured according to the embodiment of the present invention.

FIG. 2a shows side view of the contact of the present invention with the top projecting from the first arm and a contact section of the tip that has a generally planar shape profile.

FIG. 2b depicts an end view of the contact and shows the preferred embodiment of the engaging tip having a narrower contact tip thickness.

FIG. 3 shows the test socket in operation and depicts the position of the contact of the present invention.

### DETAILED DESCRIPTION OF THE DRAWINGS

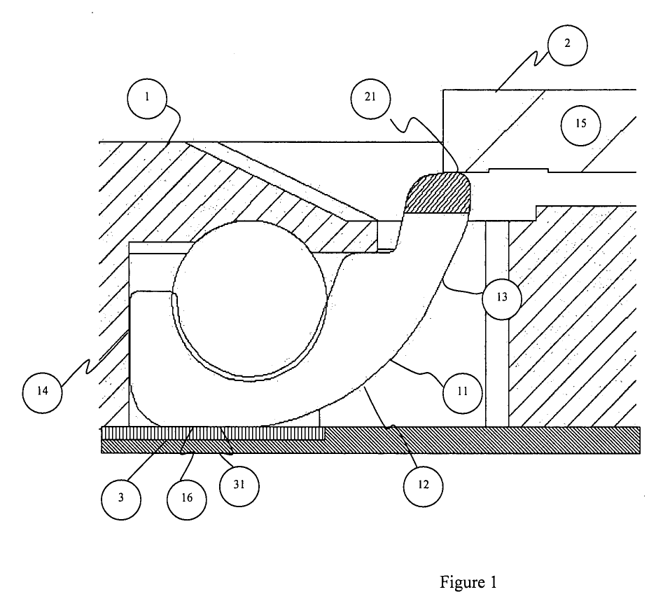

Referring first to FIG. 1 where the general view of the contact according to one preferred embodiment of the present invention installed in the test socket (1) is shown. According to the broadest aspect of the present invention, the contact (11) comprises a contact body (12), a first arm (13) and a second arm (14). The contact body (12) is generally of a W-shaped body made of conductive material such as metal or precious metal, and having two opposing arms, a first arm (13) and a second arm (14). It is preferably made from a sheet material having the required thickness, profile and stamped to shape. The loop that formed in between the arms is adapted for engaging an elastomer (23) for holding the contact (11) in position during testing.

The first arm (13) is adapted for electronically engaging the pads/leads (21) of the IC devices (2) to be tested to the contact (11). The tip of the first arm (13) has a first engaging means (15) that is provided with a sliding means for improved sliding action with the pads/leads (21). A good sliding action is generally achieved when the contact pressure between the pads/leads (21) and the sliding means is just right and this is provided by the biasing action of the elastomer (23) that imparts the desired contact for a good electric flow but not particularly excessive to be detrimental to the terminals (31) through good rolling action, as well as to the pads/leads (21) of the IC devices. Preferably, the sliding means is made from a resilient material such as Beryllium Copper and to be able to vary and compensate the contact pressure to accommodate for the different types of lead profiles and configurations.

Still referring to FIG. 1, the second arm (14) is adapted for electronically engaging the contact (11) with the corresponding terminals (31) on the printed circuit board (3) of the test handler. The second arm (14) is provided with a second engaging means (16) which extending around the exterior edge of the second arm (14). Unlike the first arm (13) that is provided with the first engaging means (15) in the form of an engaging tip (25), the second arm (14) is not provided with such engaging tip. Instead the rounded contact surface on the exterior edge of the second arm (14) providing the second engaging means (16) and also provides means to regulate and compensate contact pressure by self-adjusting its position with respect to the profile and configuration of the pads/leads.

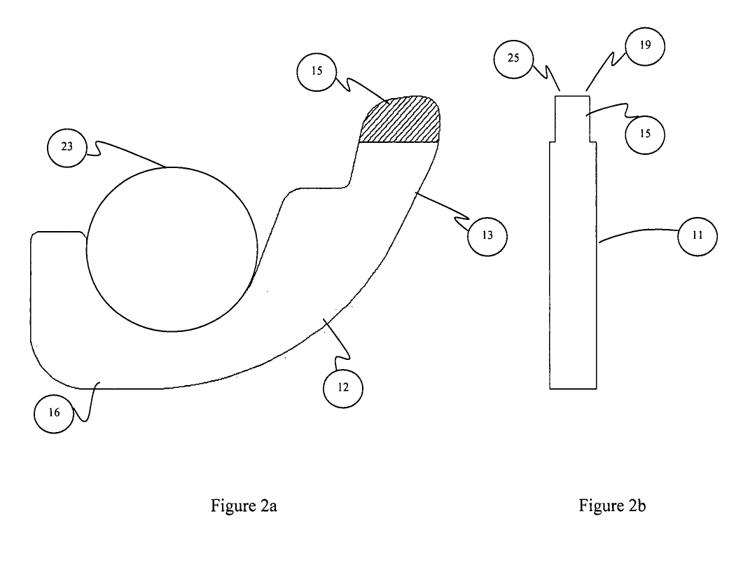

Referring now to FIG. 2a that shows the side view, and FIG. 2b that shows the front view of the contact according to the embodiment of the present invention. The contact (11) according to the embodiment of the present invention is generally to resemble a W-shaped body made of conductive material. The bent portion of the W-section acting as the arm that provides contact from the pads/leads of the IC devices to the printed circuit board (3) of the test handler. The contacting portion of the first arm (13) acting as a first engaging means (15) provided with the sliding means (15) through the engaging tip (25) projecting from the outside edge of the first arm (13). In the preferred mode of the device, the engaging tip (25) has a thickness which is less than the thickness of the first arm (13) and/or the thickness of the contact body (12). The narrower configuration provides means to accommodate plurality of different types of pads/leads (21) profiles and configurations by electronically engaging the pads/leads (21) along a narrower contact tip thus allows electrical contact with narrower pads/leads while allowing contact with wider pads/leads (21) which might have recess depressions or other impediments that would render non-clean contact to the printed circuit board of the test handler. Preferably, the engaging tip (25) is made of homogenous material and is manufactured integral with the contact body (12). In the alternative, the engaging tip (25) may be made from a different material brazed onto the first arm (13).

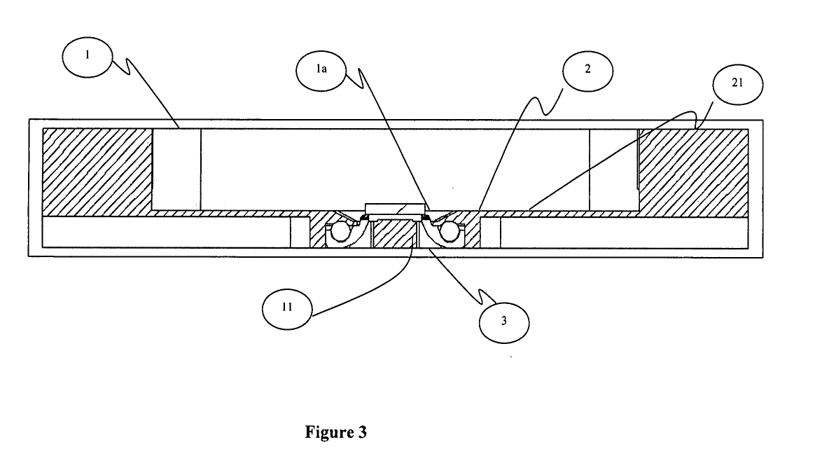

FIG. 3 shows the test socket in manual operation mode. The test socket (1) is provided with a test cavity (1a) to interconnect the printed circuit board (3) of the test handler to the pads/leads (21) of the IC devices (2). The engaging tip (25) has a thickness less than that of the thickness of the first arm (13) and advantageously allows for the utilization of only one type of contact to accommodate numerous different types of IC devices pads/leads and pitches. This feature could advantageously reduces stock requirement and eases inventory control since only one type of contact needs to be retained. As such, for daily operation, downtime during testing may also be considerably reduced.

While the preferred embodiment of the present invention and their advantages have been disclosed in the above Detailed Description, the invention is not limited thereto but only by the scope of the appended claim.

1. In a test socket (1) for testing integrated circuit devices (2) a contact (11) is provided for electronically interfacing pads/leads (21) of said integrated circuit devices (2) to be tested with corresponding terminals (31) on a printed circuit board (3), said contact (11) comprising:
a contact body (12), said contact body having a first arm (13) configured for electronically engaging said pads/leads (21), said first arm (13) being provided with a first engaging means (15), and a second arm (14) adapted for electronically engaging said corresponding terminals (31) on said printed circuit board (3), said second arm (14) being provided with a second engaging means (16);
said first arm (13) and said second arm (14) being located at opposing extremities of said contact body (12); and
said first engaging means (15) is provided with a sliding means for improved sliding action with said pads/leads (21);
characterized in that:
said sliding means includes an engaging tip (25) integrally formed on said first engaging means (16), said engaging tip (25) having narrower cross-section at its top portion relative to said contact body (12).

2. A contact (11) for a test socket (1) as claimed in claim 1, further characterized in that said narrower contact tip being integrally formed with said first arm (13).

3. A contact (11) for a test socket (1) as claimed in claim 2, further characterized in that said narrower contact tip of said engaging tip (25) having a reduced thickness, said thickness being less than that of said contact body (12).

4. A contact (11) for a test socket (1) as claimed in claim 1, further characterized in that engaging tip (25) being made from the same material as that of said first arm (13).

5. A contact (11) for a test socket (1) as claimed in claim 1, further characterized in that said engaging tip (25) being made from a different material as that of said first arm (13).

6. A contact (11) for a test socket (1) as claimed in claim 1, further characterized in that said engaging tip (25) being brazed onto said first arm (13).

7. A contact (11) for a test socket (1) as claimed in claim 1, further characterized in that said narrower engaging tip (25) having a planar edge portion, said planar edge portion positioned to contact one of said pads/leads (21).

8. A contact (11) for a test socket (1) as claimed in claim 7, further characterized in that said narrower engaging tip (25) having a reduced thickness along said planar edge portion, said thickness being less than that of said contact body (12).

9. A contact (11) for a test socket (1) as claimed in claim 8, further characterized in that said reduced thickness of said planar edge portion providing means to avoid contact impediments present or formed on or in-between said pads/leads (21).

10. A contact (11) for a test socket (1) as claimed in claim 3, further characterized in that said reduced thickness is set at about 20-60 percent less than of the thickness of said contact body (12).

11. A contact (11) for a test socket (1) as claimed in claim 3, further characterized in that said reduced thickness is set at about 20-40 percent less than of the thickness of said contact body (12).
